(19) United States
(12) Patent Application Publication
(10) Pub. No.: US 2011/0162704 A1
(43) Pub. Date: Jul. 7, 2011

(54) RELIABILITY OF BACK END OF LINE PROCESS BY ADDING PVD OXIDE FILM

(75) Inventors: Hien-Minh Huu Le, San Jose, CA (US); Mohd Fadzli Anwar Hassan, Sunnyvale, CA (US); David Tanner, San Jose, CA (US)

(73) Assignee: APPLIED MATERIALS, INC., Santa Clara, CA (US)

(21) Appl. No.: 12/965,251

(22) Filed: Dec. 10, 2010

Related U.S. Application Data
(60) Provisional application No. 61/293,135, filed on Jan. 7, 2010.

(51) Int. Cl. H01L 31/0216; C23C 14/34; H01L 31/18

(52) U.S. Cl. 136/256; 204/298.02; 438/64; 29/729; 257/E31.119

(57) ABSTRACT

A method and apparatus for forming a protective coating on a photovoltaic device is provided. The photovoltaic device is formed by depositing photoelectric conversion units on a substrate, and by forming conductive layers and contacts on the photoelectric conversion units. The protective coating is formed by a deposition process, such as physical or chemical vapor deposition.

### CROSS-REFERENCE TO RELATED APPLICATIONS

This application claims benefit of U.S. provisional patent application Ser. No. 61/293,135, filed Jan. 7, 2010, which is herein incorporated by reference.

### BACKGROUND OF THE INVENTION

1. Field of the Invention

Embodiments of the invention generally relate to fabrication of photovoltaic devices. More specifically, embodiments of the invention relate to back-end and finishing processes for photovoltaics fabrication.

2. Description of the Related Art

Photovoltaic energy generation was the fastest growing energy source in 2007. In 2008, installed photovoltaic capacity increased approximately ⅔ to about 15 GW. By some estimates, the global market for photovoltaic power will grow at a compound annual rate of 32% between 2008 and 2013, reaching over 22 GW, while installed capacity grows at an average rate of 20-30% per year or more, possibly reaching 35 GW by 2013. With available solar resources estimated at 120,000 TW, using less than 0.013% of these available resources could replace fossil fuels and nuclear energy as sources of electrical power. Total global energy consumption of 16 TW in 2005 is less than 0.02% of available solar energy incident on the earth.

With so much potential, countries and companies around the world are racing to increase efficiency, and lower cost of, photovoltaic power generation. Fabrication of photovoltaic panels requires highly complex and costly equipment that is expensive to operate and maintain. Thus, there is a need for methods and an apparatus that are able to produce efficient and cost effective photovoltaic panels.

### SUMMARY OF THE INVENTION

Embodiments disclosed herein provide a photoelectric conversion device, comprising a photoelectric conversion unit formed on a substrate, a contact layer formed on the photoelectric conversion unit, a metal protective layer formed on the contact layer, and a ceramic layer formed on the metal protective layer.

Other embodiments provide a method of forming a photoelectric device, comprising forming a photoelectric conversion unit on a substantially transparent substrate, forming a conductive layer on the photoelectric conversion unit, forming a first protective layer on the conductive layer by a first vapor deposition process, and forming a second protective layer on the first protective layer by a second vapor deposition process.

Other embodiments provide an apparatus for manufacturing a photoelectric conversion panel, comprising a first surface patterning chamber, one or more PECVD chambers, a second surface patterning chamber, a first PVD chamber, a third surface patterning chamber, a substrate sizing chamber, a substrate edge deletion chamber, a connector formation chamber, a second PVD chamber, a finishing chamber, and a plurality of automation devices configured to serially transfer a plurality of substrates to the first surface patterning chamber, the one or more PECVD chambers, the second surface patterning chamber, the first PVD chamber, the third surface patterning chamber, the substrate sizing chamber, the substrate edge deletion chamber, the connector formation chamber, the second PVD chamber, and the finishing chamber.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B are schematic cross-sectional diagrams of single and tandem-junction photoelectric conversion units, respectively, according to two embodiments.

FIGS. 2A and 2B are top views of a substrate undergoing stages of a process according to another embodiment.

FIG. 3 is a plan view of an apparatus for forming photoelectric conversion devices according to another embodiment.

FIG. 4 is a cross-sectional view of a PVD chamber that may be used to practice embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

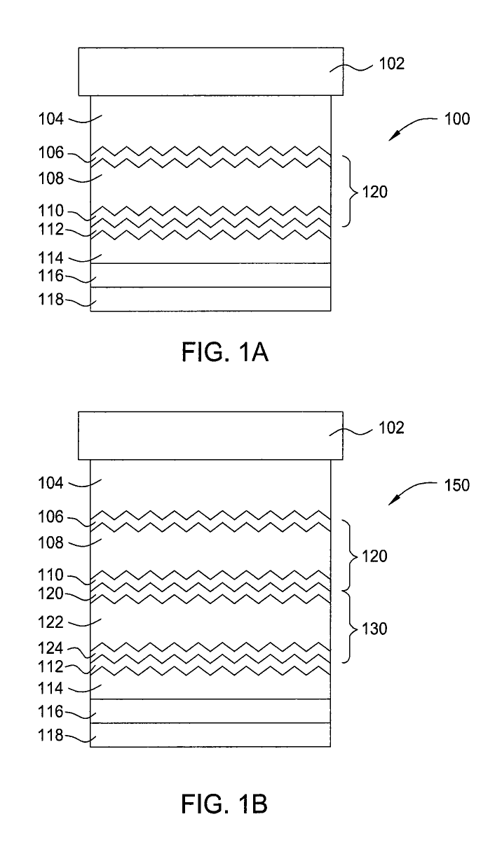

Embodiments described herein generally provide methods and apparatus for fabricating novel photoelectric conversion units. FIGS. 1A and 1B are schematic cross-sectional views of photoelectric conversion devices 100 and 150, respectively, according to two embodiments. FIG. 1A illustrates a single junction photoelectric conversion unit 100, generally comprising a substrate 102, a first conductive layer 104, a p-i-n junction 120 formed over the first conductive layer 104, a second conductive layer 112, a third conductive layer 114, which is also generally reflective, and a first and second protective layer 116 and 118, respectively. The substrate 102 is generally glass, polymer, or metal, and provides structural strength to the device. Photoelectric conversion panels may be formed on substrates of any convenient size up to nearly 6 m² in area. In one exemplary embodiment, a glass substrate having dimensions of about 2200 mm×2600 mm×3 mm is used. The size of individual photoelectric conversion units may also be determined by dividing larger panels into smaller units after forming most of the active structures of the panel.

The first conductive layer 104 may be a conductive oxide layer, and is transparent in many embodiments. In some embodiments, the first conductive layer 104 may comprise zinc oxide (ZnO) or tin oxide (SnO). In some embodiments, the first conductive layer 104 is a front contact layer for the photoelectric conversion unit. In embodiments wherein the first conductive layer 104 is a conductive oxide layer, the conductive oxide may comprise zinc (Zn), tin (Sn), indium (In), aluminum (Al), copper (Cu), silver (Ag), nickel (Ni), vanadium (V), or mixtures thereof. To improve light absorption by enhancing light trapping, the substrate and/or one or more of thin films formed thereover may be optionally textured by wet, plasma, ion, and/or mechanical processes. For example, in the embodiment shown in FIG. 1A, the first conductive layer 104 is textured, and the subsequent thin films deposited thereover generally follow the topography of the textured first conductive layer 104. The first conductive layer 104 is generally formed to a thickness between about 100 Å and about 500 Å using any convenient film formation process, such as any vapor deposition process, for example a physical vapor deposition process like sputtering. In some embodiments, a reactive sputtering process is used to deposit a metal oxide layer. For example, a metal target may be sputtered in an oxygen-containing atmosphere to deposit a metal oxide layer.

The p-i-n junction 120 generally comprises a p-type doped semiconductor layer 106, an intrinsic or undoped semiconductor layer 108, and an n-type doped semiconductor layer 110. Silicon is frequently used as the semiconductor in many embodiments, but other semiconductors, such as germanium, or compound semiconductors such as group III/V semiconductors, CIGS semiconductors, and other such compounds, may be used. P-type dopants generally include group III elements, such as boron (B) or aluminum (Al), in many embodiments. N-type dopants generally include group V elements, such as phosphorus (P), arsenic (As), or antimony (Sb), in many embodiments.

The layers of p-i-n junctions as described above are generally formed by a vapor deposition process such a chemical vapor deposition, which may be plasma-enhanced to improve deposition rate. For silicon-based films, a silicon-containing precursor is provided to a deposition chamber having a substrate disposed therein for film deposition. Exemplary silicon-containing precursors include, but are not limited to, silane (SiH₄), disilane (Si₂H₆), silicon tetrafluoride (SiF₄), silicon tetrachloride (SiCl₄), dichlorosilane (SiH₂Cl₂), and combinations thereof. A hydrogen-containing precursor, frequently hydrogen gas (H₂) itself, may also be provided to assist in controlling morphology of the deposited film. Dopants are added by adding dopant precursors to the gas mixture for deposition. Commonly used p-type dopant precursors include, but are not limited to, trimethylboron (TMB or B(CH₃)₃), trimethylaluminum (TMA or Al(CH₃)₃), diborane (B₂H₆), boron trifluoride (BF₃), triethylboron (B(C₂H₅)₃), and other similar compounds, sometimes in mixtures. Commonly used n-type dopant precursors include, but are not limited to, phosphine (PH₃) and arsine (AsH₃). Dopants may be delivered using carrier gases, such as H₂, argon (Ar), helium (He), and mixtures thereof.

In one aspect, the p-type doped semiconductor layer 106 is formed over the first conductive layer 104 to a thickness between about 60 Å and about 300 Å, the intrinsic semiconductor layer 108 may be formed to a thickness between about 1,500 Å and about 3,500 Å, and the n-type semiconductor layer 110 may be formed to a thickness between about 100 Å and about 400 Å. Different morphologies are sometimes used to capture broader portions of the electromagnetic spectrum, so in one exemplary embodiment, the p-type and intrinsic layers may have an amorphous morphology, while the n-type layer has a crystalline morphology such as microcrystalline, polycrystalline, multicrystalline, or monocrystalline.

The second and third conductive layers 112 and 114 form a back contact layer for the photoelectric conversion unit 100. The second conductive layer 112 has composition generally similar to the composition of the first conductive layer 104 as described above, and may be formed by any similar process. In one embodiment, the third conductive layer 114 is generally metal, such as a material selected from the group consisting of aluminum (Al), silver (Ag), titanium (Ti), chromium (Cr), gold (Au), copper (Cu), platinum (Pt), mixtures thereof, combinations thereof, and alloys thereof, to provide a light-capturing reflective surface. The third conductive layer 114 may be formed by any convenient process, and is frequently formed using a vapor deposition process, such as physical or chemical vapor deposition, which may be plasma enhanced. In some embodiments, a physical vapor deposition process like sputtering is used to form the third conductive layer 114.

The first and second protective layers 116 and 118 may have the same composition or may be layers of different composition. The protective layers 116 and 118 generally provide protection from moisture and oxygen in the atmosphere, which may cause corrosion to unprotected components of photoelectric conversion panels, and protection from physical damage under some circumstances. The second protective layer 118, which is the outer protective layer in the embodiment of FIG. 1A, may be a ceramic material, such as a thick metal oxide material, in some embodiments. Materials suitable for such layers include, but are not limited to, titanium oxide (TiOₓ), zinc oxide (ZnO), tantalum oxide (TaₐO_{b}). The stoichiometric quantities x, a, and b may vary within films and from film to film. For example, in a tantalum oxide film, process conditions of deposition may be adjusted to control the ratio of oxygen atoms to tantalum atoms (b/a) between about 2.2 and about 3.1, with the nominal stoichiometric value being about 2.5. Likewise the ratio of oxygen to titanium (x) in titanium oxide may vary between about 1.8 and about 2.2, with the nominal stoichiometric value being about 2.0.

The second protective layer 118 is generally formed to a thickness greater than about 2 μm, such as between about 2 μm and about 300 μm, for example about 10 μm, to provide a robust and durable outer layer. To ensure good adhesion of the second protective layer 118 to the layers beneath, the second protective layer 118 is generally deposited with low residual film stress of less than about 150 MPa, which may be tensile or compressive, depending on the method of depositing the film, the film composition, crystal structure of the deposited film and film morphology. In one example, the second protective layer 118 is amorphous. When formed by processes tending to produce smooth films, the second protective layer 118 may have surface roughness less than about 3 nm, or less than 2 nm, for example between about 0.1 nm and about 1.0 nm, or between about 0.2 nm and about 0.3 nm. The second protective layer 118 may also have a refractive index between about 2.0 and about 3.0, such as between about 2.2 and about 2.5, which may depend on the thickness, composition, and morphology of the second protective layer 118.

The second protective layer 118 may be formed using any convenient process. In one aspect, a physical vapor deposition (PVD) process may be used. In an embodiment wherein the second protective layer 118 comprises tantalum oxide, a reactive sputtering process may be performed by sputtering a tantalum target in an oxygen atmosphere. A gas mixture comprising argon and oxygen may be provided to a sputtering chamber having a tantalum target, and the target biased with RF, DC, or pulsed DC power to stimulate sputtering. In one example, the gas mixture is provided to the chamber at a flow rate between about 100 sccm and about 20,000 sccm depending on the chamber volume and substrate size. The gas mixture will generally contain between about 1% and about 50% oxygen by volume, such as between about 5% and about 20%, for example about 10%. The chamber may be operated at a pressure between about 1 mTorr and about 10 Torr, such as about 1 Torr. In one example, the target is biased using DC power between about 500 W and about 5,000 W at a voltage between about 100 V and about 10 kV. The substrate temperature during deposition is generally less than about 200° C., such as between about 25° C. and about 150° C., for example about 80° C. Deposition processes such as these may be performed using an ATON™ PVD 5.7 tool available from Applied Materials, Inc., located in Santa Clara, Calif. In another embodiment, a plasma spray, flame spray or arc spray deposition technique may be used to deposit the second protective layer 118.

The second protective layer 118 is formed over the first protective layer 116, which in turn is formed over the third conductive layer 114. The first protective layer may have the same or similar constitution as the second protective layer 118, or it may have a different constitution. In one embodiment, the first protective layer 116 is a nickel-vanadium (NiV) alloy, while the second protective layer 118 is a ceramic material, such as those described above. In another embodiment, aluminum is added to the NiV. It should be noted that a first protective layer 116 comprising metal, such as NiV alloy, will also be reflective and conductive, and may therefore be integrated with the third conductive layer 114 in some embodiments. Thus, some embodiments, may have a third conductive layer 114 comprising an NiV alloy, and the first protective layer 116 may be eliminated such that the second protective layer 118 is formed on the third conductive layer 114 comprising the NiV alloy. The first protective layer 116 may be formed using a PVD, a plasma spray, a flame spray or an arc spray deposition technique.

FIG. 1B illustrates a multi-junction photoelectric conversion unit 150, which in this case is a tandem-junction unit. The photoelectric conversion unit 150 generally comprises the elements of the single junction photoelectric conversion unit 100 of FIG. 1A, with a second p-i-n junction 130, comprising a second p-type semiconductor layer 120, a second intrinsic semiconductor layer 122, and a second n-type semiconductor layer 124, added between the first p-i-n junction 120 and the second conductive layer 114. The second p-i-n junction 130 may be formed according to any of the compositions and characteristics described above in connection with formation of the first p-i-n junction, and may have any desired morphology. In one embodiment of a tandem-junction photoelectric conversion unit, the first p-i-n junction 120 will have amorphous p-type and intrinsic layers 106 and 108, with a microcrystalline n-type layer 110, and the second p-i-n junction will have microcrystalline p-type and intrinsic layers 120 and 122, with an amorphous n-type layer 124. The different morphologies broaden the spectral range of absorption, and amorphous layers may act as a barrier to avoid contamination and/or diffusion of oxygen species into the formed device during processing.

In one embodiment, the layers 120, 122, and 124 of the second p-i-n junction 130 are thicker than the layers 106, 108, and 110 of the first p-i-n junction 120. For example, in one embodiment, the second p-type semiconductor layer 120 may have a thickness between about 100 Å and about 400 Å, the second intrinsic semiconductor layer 122 may have a thickness between about 10,000 Å and about 30,000 Å, and the second n-type semiconductor layer may have a thickness between about 100 Å and about 500 Å.

Information regarding the hardware and processing methods used to deposit one or more layers in the p-i-n junctions is further described in U.S. patent application Ser. No. 12/178,289, filed Jul. 23, 2008, and U.S. patent application Ser. No. 12/170,387, filed Jul. 9, 2008, which are both herein incorporated by reference.

Exemplary recipes for forming amorphous and microcrystalline doped and intrinsic silicon layers for a p-i-n junction as described in connection with FIGS. 1A and 1B are provided below. Amorphous layers are generally formed by providing a gas mixture of hydrogen gas to silane gas in a ratio of about 20:1 or less to a plasma deposition chamber containing a substrate to be processed. Microcrystalline layers are generally formed at silane to hydrogen ratios of 100:1 or more, and in some cases 200:1 or more. Microcrystalline layers formed by these recipes generally have crystal fraction between about 20 percent and about 80 percent, such as between about 50 percent and about 70 percent. The doped layers formed by the following recipes generally have dopant concentrations between about 1×10¹⁸ atoms/cm² and about 1×10²⁰ atoms/cm².

To form a p-type amorphous silicon layer, silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. RF power between about 15 mW/cm² and about 200 mW/cm² may be provided to assist deposition. The pressure of the chamber is generally maintained between about 0.1 Torr and 20 Torr, preferably between about 1 Torr and about 4 Torr.

Methane or other carbon containing compounds, such as C₃H₈, C₄H₁₀, C₂H₂, can be used to improve the window properties (e.g., to lower absorption of solar radiation) of a p-type amorphous silicon layer. In the embodiment described above, methane may be provided at a flow rate between about 1 sccm/L and 15 sccm/L. In the embodiment wherein the methane gas is used to form the p-type layer as a silicon carbide layer, the carbon dopant concentration is controlled between about 10 atomic percent and about 20 atomic percent of the layer.

To form an intrinsic amorphous silicon, silane gas may be provided at a flow rate between about 0.5 sccm/L and about 7 sccm/L. Hydrogen gas may be provided at a flow rate between about 5 sccm/L and 60 sccm/L. An RF power between 15 mW/cm² and about 250 mW/cm² may be provided. The pressure of the chamber may be maintained between about 0.1 Torr and 20 Torr, preferably between about 0.5 Torr and about 5 Torr. In an exemplary embodiment, the intrinsic type amorphous silicon layer is deposited at a hydrogen to silane ratio at about 12.5:1.

To form an n-type amorphous silicon layer, silane gas may be provided at a flow rate between about 1 sccm/L and about 10 sccm/L, such as about 5.5 sccm/L. Hydrogen gas may be provided at a flow rate between about 4 sccm/L and about 40 sccm/L, such as about 27 sccm/L. Phosphine may be provided at a flow rate between about 0.0005 sccm/L and about 0.0015 sccm/L, such as about 0.0095 sccm/L. If phosphine is provided in a 0.5% molar or volume concentration in a carrier gas, then the dopant/carrier gas mixture may be provided at a flow rate between about 0.1 sccm/L and about 3 sccm/L, such as about 1.9 sccm/L. An RF power between 25 mW/cm² and about 250 mW/cm², such as about 80 mW/cm², may be provided. The pressure of the chamber may be maintained between about 0.1 Torr and about 20 Torr, preferably between about 0.5 Torr and about 4 Torr, such as about 1.5 Torr. In an exemplary embodiment, the n-type type amorphous silicon layer is deposited at a hydrogen to silane ratio at about 5.5:1.

To form a p-type microcrystalline silicon layer, silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. If trimethylboron is provided in a 0.5% molar or volume concentration in a carrier gas, then the dopant/carrier gas mixture may be provided at a flow rate between about 0.04 sccm/L and about 0.32 sccm/L. An RF power between about 50 mW/cm² and about 700 mW/cm² may be provided. The pressure of the chamber may be maintained between about 1 Torr and about 100 Torr, preferably between about 3 Torr and about 20 Torr.

To form an intrinsic microcrystalline silicon layer, silane gas may be provided at a flow rate between about 0.5 sccm/L and about 5 sccm/L. Hydrogen gas may be provided at a flow rate between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. An RF power between about 300 mW/cm² or greater, preferably 600 mW/cm² or greater, may be provided. In certain embodiments, the power density may be ramped down from a first power density to a second power density during deposition. The pressure of the chamber is maintained between about 1 Torr and about 100 Torr, preferably between about 3 Torr and about 20 Torr.

To form an n-type microcrystalline silicon layer, silane gas may be provided at a flow rate between about 0.1 sccm/L and about 0.8 sccm/L, such as about 0.35 sccm/L. Hydrogen gas may be provided at a flow rate between about 30 sccm/L and about 250 sccm/L, such as about 71.43 sccm/L. Phosphine may be provided at a flow rate between about 0.0005 sccm/L and about 0.006 sccm/L. If phosphine is provided in a 0.5% molar or volume concentration in a carrier gas, then the dopant/carrier gas may be provided at a flow rate between about 0.1 sccm/L and about 1.2 sccm/L. An RF power between about 100 mW/cm² and about 900 mW/cm² may be provided. The pressure of the chamber may be maintained between about 1 Torr and about 100 Torr, preferably between about 3 Torr and about 20 Torr.

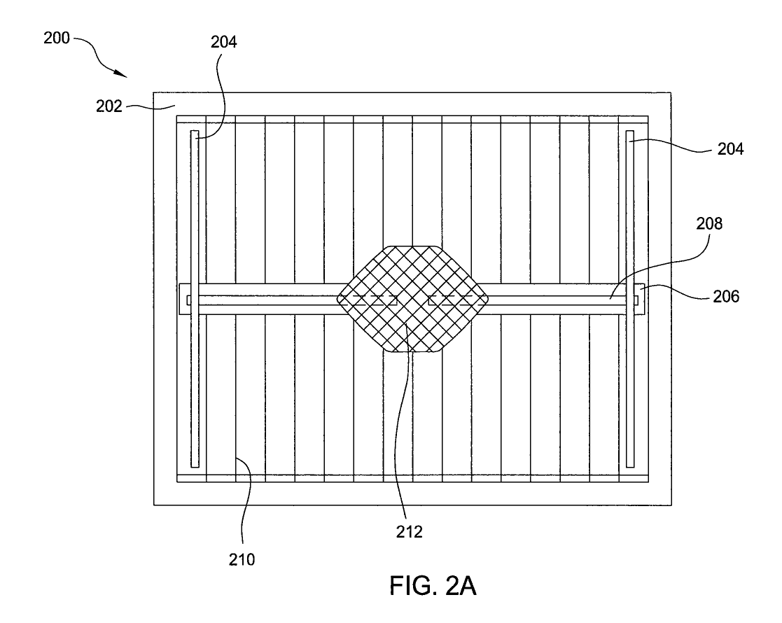

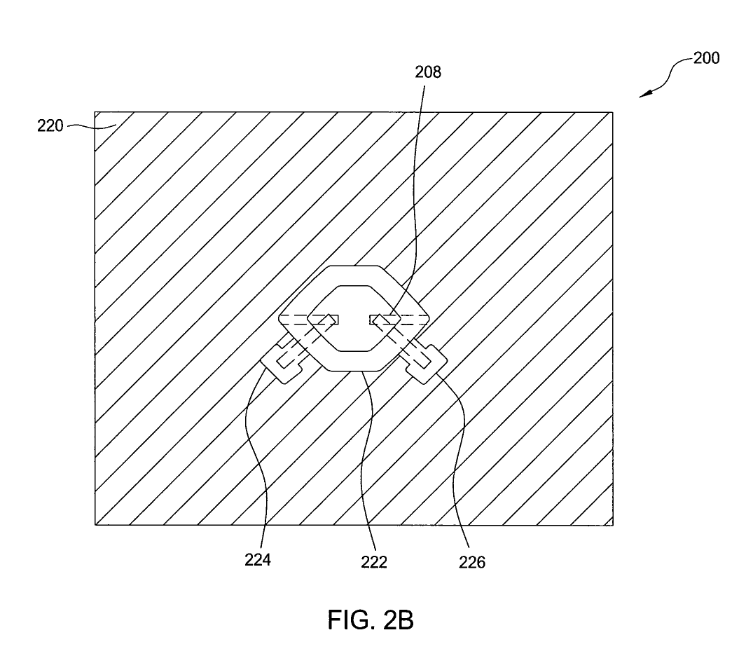

FIGS. 2A and 2B are top views of a photoelectric conversion unit 200 at two different stages of fabrication. In FIG. 2A, the photoelectric conversion unit 200 comprises a substrate 202, which in turn comprises one or more p-i-n junctions formed over a first conductive layer and structural substrate, with a back contact layer, as described above in connection with the devices of FIGS. 1A and 1B. The photoelectric conversion unit 200 also comprises first connector 204 and second connector 208 applied to the back contact layer of the substrate 202 for collecting current produced by the photoelectric conversion unit 200.

In one embodiment, the first connector 204 is a side-buss and the second connector 208 is a cross-buss. In this configuration the side-buss 204 may be a conductive material that can be affixed, bonded and/or fused to the back contact layer found in the back contact region to form a good electrical contact. In one embodiment, the side-buss 204 and cross-buss 208 each comprise a metal strip, such as copper tape, a nickel coated silver ribbon, a silver coated nickel ribbon, a tin coated copper ribbon, a nickel coated copper ribbon, or other conductive material that can carry the current delivered by the solar cell and be reliably bonded to the metal layer in the back contact region. In one embodiment, the metal strip is between about 2 mm and about 10 mm wide and between about 1 mm and about 3 mm thick. The cross-buss 208, which is electrically connected to the side-buss 204, can be electrically isolated from the back contact layer(s) of the solar cell by use of an insulating material 206, such as an insulating tape. The ends of each of the cross-busses 208 generally have one or more leads that are used to connect the side-buss and cross-buss formation to the electrical connections found in a junction box (item 222 of FIG. 2B), which is used to connect the formed solar cell to the other external electrical components. For further information on soldering bus wire to thin film photoelectric conversion units, please see U.S. Provisional Patent Application Ser. No. 60/967,077, U.S. Provisional Patent Application Ser. No. 61/023,810, and U.S. Provisional Patent Application Ser. No. 61/032,005, each of which is incorporated by reference herein.

The photoelectric conversion unit 200 of FIG. 2A further comprises grooves 210 for isolating individual cells on the photoelectric conversion unit 200. The grooves may be formed by any convenient process. In one embodiment, the grooves are formed by a laser ablation or laser scribing process. Such a process may be accomplished using any sufficiently energetic laser, such as a Nd:YAG or Nd:YVO₄ laser. In one embodiment, a pulsed 1054 nm laser is used to scribe grooves in the back conductive layers of the photoelectric conversion unit 200. The front-side conductive layers are also generally isolated in a similar fashion. In alternate embodiments, a water jet cutting tool or diamond scribe may be used.

In order to use a ceramic material as a protective layer for the photoelectric conversion unit 200, the portion of the substrate 202 that is to be coupled to the junction box 222 in FIG. 2B is masked at region 212 to protect the portions of the cross-busses 208 that will connect to the junction box 222. After the protective layer is deposited at region 220 in FIG. 2B, the mask is removed, and the junction box 222 attached. The terminals 224 and 226 of the junction box 222 are electrically connected to the second connectors 208 to finish the photoelectric conversion unit 200.

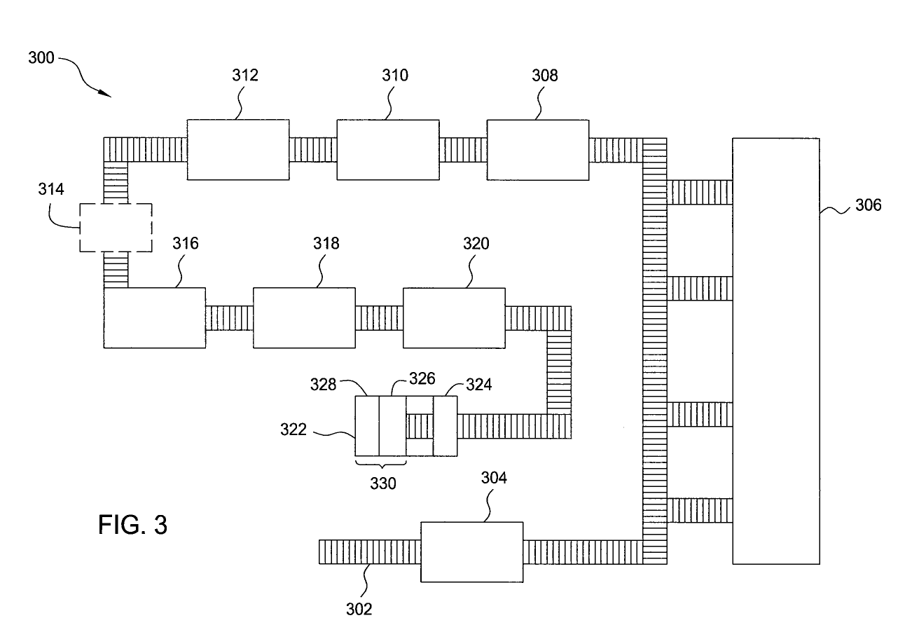

FIG. 3 is a plan view of an apparatus 300 for fabricating a photoelectric conversion unit such as those described in connection with FIGS. 1A-2B. The apparatus 300 generally comprises a plurality of modules for depositing material on a substrate and removing material on a substrate according to different processes. The modules are generally coupled together by a plurality automation devices 302 that serially transfer substrates among the modules according to a processing method implemented by the arrangement of the modules.

The apparatus 300 comprises a first surface patterning module 304 for scribing a pattern on the surface of a substrate by removing surface material from the substrate. Each of the surface patterning modules, including the first surface patterning module 304 and those surface patterning modules described below, may individually be a laser scribing tool, a pressurized water cutting tool, or a diamond scribe according to any of the embodiments described above in connection with FIG. 2A. A substrate comprising a structural base and a first conductive layer formed on the structural base is provided to the automation device 302, which transfers the substrate into the first surface patterning module 304. The first surface patterning module 304 forms an isolation pattern in the first conductive layer of the substrate, as described in connection with FIG. 2A.

An automation device 302 then transfers the substrate to a PECVD module 306. The active layers of the emerging photoelectric conversion unit are formed in the PECVD module 306. The PECVD module generally comprises one or more PECVD chambers or clusters of PECVD chambers adapted to deposit doped and undoped semiconductor layers to form p-i-n junctions on the substrate. An embodiment of a PECVD module suitable for such processes is described in paragraphs 107-114 of commonly assigned United States Patent Application Publication No. 2009/0077805 (APPM/11141), which is hereby incorporated in its entirety to the extent not inconsistent with the present disclosure.

After formation of one or more p-i-n junctions on the substrate in the PECVD module 306, an automation device 302 transfers the substrate to a second surface patterning module 308, which may be generally similar to the first surface patterning module 304. The second surface patterning module 308 forms a pattern of lines in the substrate for isolating individual photoelectric conversion cells of the emerging photoelectric conversion unit. Grooves, which may eventually become the grooves 210 of FIG. 2A for a processing regime adapted to produce the isolation pattern of FIG. 2A, are formed in the PECVD deposited layers to delineate the individual cells. The grooves are generally formed by a precision material removal process as described above in connection with FIG. 2A.

An automation device 302 then transfers the substrate to a first PVD module 310 that forms a back contact layer on the substrate. The back contact layer may be similar to the second and third conductive layers 112 and 114 described above in connection with FIGS. 1A and 1B. The first PVD module may comprise a plurality of PVD chambers adapted to deposit a plurality of layers on the substrate.

An automation device 302 then transfers the substrate to a third surface patterning module 312, adapted to form an isolation pattern in the back contact layer. In general, the isolation pattern will conform to the isolation pattern formed in the PECVD layers in the second surface patterning module 308. Grooves are scribed into the back contact layer using a precision material removal process, which may be generally similar to that performed by either the first or second surface patterning modules 304 and 308, and may be similar to the scribing processes described above in connection with FIG. 2A.

An automation device 302 then transfers the substrate to an optional substrate sizing module 314, which may be configured to cut a large substrate into smaller substrates prior to finishing. In one embodiment, the substrate sizing module 314 is configured to section a large substrate into four substantially equal smaller substrates. For example, in one embodiment, the substrate sizing module 314 is configured to accept a 5.7 m² substrate and accurately cut it into four 1.4 m² substrates. In another embodiment, the substrate sizing module 314 is configured to accept a substrate having dimensions 2,200 mm×2,600 mm×3 mm and produce various sized photoelectric conversion units from the substrate without additional equipment or processing steps.

An automation device 302 then transfers the substrate (or substrates if using the optional substrate sizing module 314) to a substrate edge deletion module 316 in which a substrate surface or edge preparation process is performed. The substrate edge deletion module 316 generally comprises one or more material removal devices, which may be frictional material removal devices such as grinding wheels or laser ablation devices, and one or more positioning devices, such as conveyors and pressure pads. The substrate edge deletion module 316 removes any material deposited in edge deletion regions of the substrate, and smoothes any edge imperfections that may cause yield issues or equipment damage in later process stages. An example of a substrate edge deletion module is described in commonly-assigned United States Patent Publication 2009/0077805, which has been incorporated in this disclosure.

An automation device 302 then transfers the substrate or substrates to a connector formation module 318. The connector formation module applies the main connectors that will couple the cells of the photoelectric conversion unit to the junction box. These main connectors may be generally similar to the connectors 204 and 208 described in FIG. 2A. In one embodiment, the connector formation module 318 is a bonding wire attach module that comprises a side connector assembly and a cross-connector assembly, each of which is a flux soldering apparatus, and a positioning system. An example of a connector formation module 318 is described in paragraphs 135-154 of commonly assigned United States Patent Publication 2009/0077805, which has been incorporated in this disclosure.

An automation device 302 then transfers the substrate or substrates to a second PVD module 320. The second PVD module forms a back protective layer on the substrate to protect electrical elements of the substrate from attack by atmospheric moisture and oxygen and from physical damage in some circumstances. The protective layer generally comprises a ceramic material, such as tantalum oxide, and may also comprise a metal alloy, such as nickel-vanadium. The protective layer is generally deposited in the second PVD module over the back contact layer.

The second PVD module may comprise a plurality of deposition stations for depositing one or more materials. In some embodiments the Applied Materials ATON PVD 5.7 tool mentioned above may be useful as a component of the second PVD module.

The second PVD module may also comprise a masking station for forming a mask over portions of the substrate that are not intended to be covered by the PVD deposited back protective layer. In one embodiment, areas of the substrate to be engaged by the junction box (e.g., region 212) may be masked to prevent covering electrical contacts with insulating material. The second PVD module may also comprise an unmasking station for removing the mask following PVD backing layer formation.

An automation device 302 then transfers the substrate or substrates to a finishing module 322. The finishing module 322 comprises a junction box attach station 324 and a testing station 330. In one embodiment, the testing station 330 includes a solar simulator 326 and a high potential station 328. The junction box attach station 324 couples a junction box to the substrate, connecting and/or soldering the junction box terminals to the substrate connectors as shown in FIG. 2B in an automated fashion. Positioners such as photodetectors and pressure pads may be used with controllers and linear actuators to position the substrate, the junction box, or both for precise attachment. Thereafter, a probe assembly (not shown) is coupled to the junction box in the solar simulator 326 to detect the power generated by the substrate in response to a flash of simulated solar light. Finally, a probe assembly (not shown) is coupled to the junction box in the high potential station 328 to apply high voltage to the connectors formed in the substrate. A probe (not shown) is coupled to the edge of the substrate, or the substrate is immersed in a conductive liquid with a probe disposed therein, to detect any current leaking from the edge of the substrate due to the high voltage. In some embodiments, one or more off-spec bins may be coupled to any of the stations of the finishing module 322 for disposal of substrates not performing to spec. An example of a junction box attachment module, a testing station, solar simulator, automation devices and other similar components found in the apparatus 300 are further described in the commonly assigned U.S. patent application Ser. No. 12/202,199, filed Aug. 29, 2008, which is incorporated by reference in its entirety.

The configuration as shown in FIG. 3 is believed to have many advantages over more conventional solar cell production lines that form solar cell devices that use a second glass substrate material and EVA or PVB material layer to encapsulate and seal the formed solar device components (e.g., solar cell junction(s), back contact layer, side-buss 204 and cross-buss 208) from environmental attack during the solar cell's service life. The advantages generally include a reduction in the manufacturing cost of a solar cell device, a reduction in manufacturing time and complexity, improved production line reliability and a reduction in the number of hardware components required to form a complete solar cell device. The reduction in the number of hardware devices is generally significant, since there is no need for a second glass substrate delivery automation device, EVA/PVB delivery automation devices, a bonding module that is used to bond the glass substrate, EVA/PVB layer and solar cell containing substrate together, and there is no need for an autoclave device that is used to drive bubbles from the EVA/PVB layer, as commonly required in conventional solar cell production lines. The production line is also generally less complex and more reliable since no automation devices and storage locations are required within the solar cell production line to hold and position the second glass substrate and EVA/PVB material on the substrate surface.

Embodiments described herein also provide a method of forming a photoelectric device. In one embodiment, one or more photoelectric conversion units are formed on a substantially transparent substrate, such as a glass substrate. In such an embodiment, the substrate admits light to the photoelectric conversion unit for power generation. In alternate embodiments, the substrate may be translucent or opaque, for example a metal or plastic substrate, if light is to be admitted at another surface of the device. The photoelectric conversion units generally comprise semiconductor materials with dopants to facilitate current collection, as described above.

In one embodiment, a conductive layer is formed on the photoelectric conversion units. The conductive layer generally comprises one or more sublayers of conductive material, such as metal, metal alloy, or metal oxide, any of which may also be reflective. In most embodiments, the conductive layer is substantially continuous across the substrate, and current collected by the conductive layer may be focused into connectors formed on portions of the conductive layer.

A first protective layer may be formed over the conductive layer to provide a barrier to moisture and oxygen from the atmosphere, which would otherwise degrade components of the photoelectric device. In one embodiment, the first protective layer is formed in a vapor deposition process, such as PVD or CVD, and may comprise a thick moisture-resistant and oxidation-resistant metal, metal alloy, or metal oxide material. For example, a nickel-vanadium alloy may be deposited over the conductive layer as a first protective layer by sputtering a nickel-vanadium target in a PVD chamber with an inert atmosphere, such as argon gas. In one aspect, the first protective layer may be incorporated into the surface of the conductive layer by co-depositing materials of the conductive layer and the first protective layer near the end of the conductive layer deposition process.

A second protective layer may be formed over the first protective layer to provide further barrier properties. In one aspect, the second protective layer may be a ceramic material, such as a thick layer of ceramic material like metal oxide. Exemplary ceramic materials for use as a protective layer include, but are not limited to, tantalum oxide, titanium oxide, zinc oxide, and combinations thereof. The ceramic materials may be deposited using a reactive PVD process, for example by sputtering a tantalum, titanium, or zinc target in an oxygen-containing atmosphere. In one embodiment, the second protective layer has a thickness of at least about 2 μm, such as between about 2 μm and about 300 μm.

Portions of the substrate may be masked prior to formation of the second protective layer to allow attachment of a connective assembly to the conductive layer and/or contacts formed on the conductive layer after the protective layer or layers are formed. The masking may be done by any convenient process, which may include any suitable deposition process. In an exemplary embodiment, a masking material may be deposited through a physical mask or stencil.

The mask material may then be removed after formation of the protective layers. To this end, the mask material is generally selected to be reactive under a chemistry that does not react with the material of the protective layer. For example, if the outer surface of the protective layer is an oxide material, such as a metal oxide, the mask material may be a carbon material removable using an oxygen chemistry. In another embodiment, the mask material may be physically applied to the substrate as an adhesive film, and then peeled off following formation of the protective layer or layers. In one embodiment, the mask material may be a glass filled tape or other similar masking material that is commonly used in thermal spraying applications.

It should be noted that in some embodiments, a ceramic or metal oxide protective layer may be deposited as the first protective layer without the metal or metal alloy protective layer.

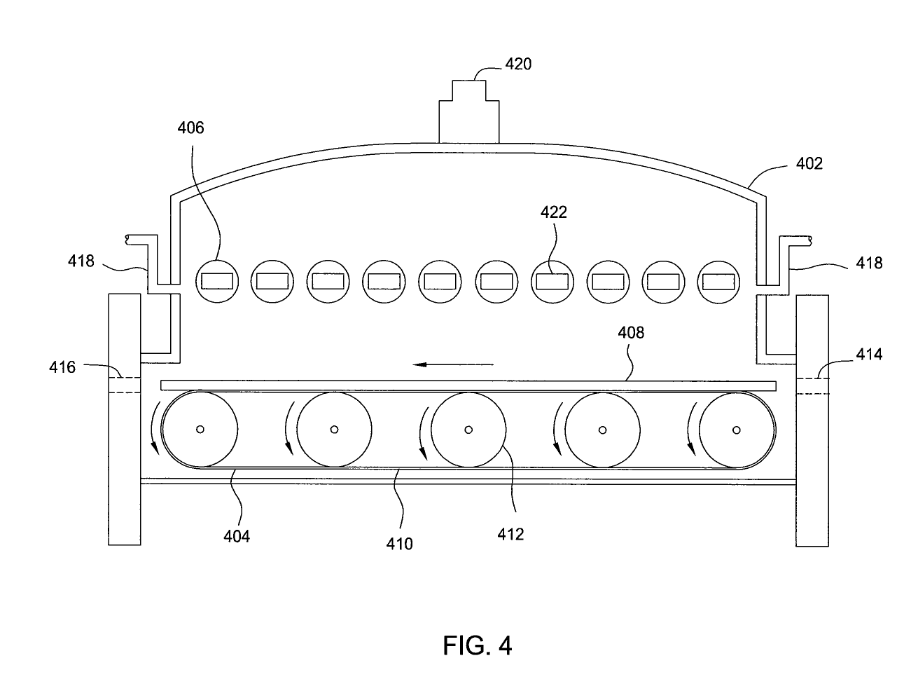

FIG. 4 is a cross-sectional view of a PVD chamber 400 that may be used to form the various protective coatings described above. The chamber 400 comprises an enclosure 402, a substrate support 404, and one or more sputtering targets 406. In the embodiment of FIG. 4, a plurality of sputtering targets 406 is provided for improved uniformity, but the protective layers described herein may be formed using one sputtering target. The substrate support 404 of FIG. 4 is a conveyor for passing a substrate 408 through the chamber 400 while depositing, but a static substrate support and deposition process may also be used. The conveyor substrate support 404 comprises a belt 410 and rollers 412, but any suitable conveyor system for substrates may be used. In a dynamic sputtering process, the substrate 408 enters the chamber through a first opening 414, is captured by the conveyor belt 410, carried through the chamber, and exits through a second opening 416 opposite the first opening 414. Sputtering gases are provided to the chamber through one or more conduits 418, and gas is evacuated from the chamber by one or more vacuum pumps 420. The sputtering targets shown in the embodiment of FIG. 4 are cylindrical rotating targets, each with a magnet assembly 422 disposed inside.

While the foregoing is directed to embodiments of the invention, other and further embodiments of the invention may be devised without departing from the basic scope thereof.

What is claimed is:

1. A photoelectric conversion device, comprising:
a photoelectric junction formed on a substrate;
a contact layer formed on the photoelectric junction;
a metal protective layer formed on the contact layer; and
a ceramic layer formed on the metal protective layer.

2. The photoelectric conversion device of claim 1, wherein the ceramic layer is a metal oxide layer.

3. The photoelectric conversion device of claim 1, wherein the ceramic layer is amorphous.

4. The photoelectric conversion device of claim 1, wherein the ceramic layer comprises tantalum.

5. The photoelectric conversion device of claim 1, wherein the ceramic layer has a thickness greater than about 2 μm and residual stress less than about 150 MPa.

6. The photoelectric conversion device of claim 1, wherein the photoelectric junction comprises a p-i-n junction, and the ceramic layer is an amorphous metal oxide layer.

7. A method of forming a photoelectric device, comprising:
forming a photoelectric junction on a substantially transparent substrate;
forming a conductive layer on the photoelectric junction;
forming a first protective layer on the conductive layer by a first vapor deposition process; and
forming a second protective layer on the first protective layer by a second vapor deposition process.

8. The method of claim 7, wherein the first protective layer is a metal layer and the second protective layer is a ceramic layer.

9. The method of claim 7, wherein the conductive layer comprises a metal oxide layer.

10. The method of claim 7, wherein the second vapor deposition process is a physical vapor deposition process.

11. The method of claim 7, further comprising masking portions of the conductive layer prior to forming either the first or the second protective layers.

12. The method of claim 11, further comprising removing the mask from the masked portions of the conductive layer, after forming the first and the second protective layers, to form exposed regions of the conductive layer, and then attaching a junction box to the exposed regions of the conductive layer.

13. The method of claim 7, wherein the second protective layer comprises tantalum.

14. The method of claim 7, wherein the second protective layer is deposited by physical vapor deposition to a thickness of at least about 2 μm.

15. An apparatus for manufacturing a photoelectric conversion panel, comprising:
one or more PECVD modules that are configured to deposit a silicon containing layer;
a first PVD module that are configured to deposit a conductive layer;
a substrate edge deletion module that is configured to remove a portion of the silicon containing layer and the conductive layer;
a connector formation module;
a second PVD module that is configured to deposit a protective layer; and
a plurality of automation devices configured to serially transfer a plurality of substrates to the one or more PECVD modules, the first PVD module, the substrate edge deletion module, the connector formation module, and the second PVD module.

16. The apparatus of claim 15, wherein the first PVD module is a contact deposition module, and the second PVD module is a back protective layer deposition module.

17. The apparatus of claim 15, further comprising a finishing module that comprises a junction box attachment station.

18. The apparatus of claim 16, wherein the second PVD module further comprises a substrate masking station and a mask removal station.

19. The apparatus of claim 18, wherein the second PVD module comprises at least two deposition stations.
